(19) United States
(12) Patent Application Publication
(10) Pub. No.: US 2007/0007600 A1
(43) Pub. Date: Jan. 11, 2007

(54) MOS transistor and method of manufacturing the same

(75) Inventors: Kyoung-Yun Baek, Anyang-si (KR); Yong-Sun Ko, Suwon-si (KR); Chun-Suk Suh, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/482,795

(22) Filed: Jul. 10, 2006

(30) Foreign Application Priority Data
Jul. 11, 2005 (KR) 2005-0062137

(51) Int. Cl. H01L 29/94

(52) U.S. Cl. 257/368

(57) ABSTRACT

Example embodiments of the present invention relate to a metal oxide semiconductor (MOS) transistor and a method of manufacturing the MOS transistor. A MOS transistor may include a substrate, a semiconductor pattern, a gate insulation layer and/or source-drain regions. The substrate may include an active region and/or a field region. The semiconductor pattern may extend from the active region and may extend along the active region in a first direction. The gate insulation layer may be formed on the substrate to cover the semiconductor pattern. The gate electrode may be formed on the semiconductor pattern. The gate electrode may have a linear shape extending in the first direction. The source-drain regions may be formed at portions of the active region adjacent to the gate electrode in a second direction substantially perpendicular to the first direction. A channel of the transistor may be formed along a sidewall and an upper surface of the semiconductor pattern in order that the channel may have a length substantially larger than a width of the gate electrode, increasing electrical characteristics of the MOS transistor.

### PRIORITY STATEMENT

This application claims priority under 35 USC §119 to Korean Patent Application No. 2005-62137 filed on Jul. 11, 2005 in the Korean Intellectual Property Office, the contents of which are incorporated herein by reference in their entirety.

### BACKGROUND OF THE INVENTION

1. Field of the Invention

Example embodiments of the present invention relate to a metal oxide semiconductor (MOS) transistor and a method of manufacturing the MOS transistor. More particularly, example embodiments of the present invention relate to an MOS transistor including a channel having a length larger than a width of a gate electrode thereof and a method of manufacturing the MOS transistor.

2. Description of the Related Art

As semiconductor devices become more highly integrated, widths of patterns in the semiconductor devices may be reduced. Intervals between the patterns may decrease. In a semiconductor memory device (e.g., a dynamic random access memory (DRAM) device), a gate electrode of a transistor in a DRAM device may have a small width when the gate electrode is formed on a semiconductor substrate by performing a semiconductor manufacturing process for a more highly integrated semiconductor device.

When a transistor is a planar type, a gate electrode of the planar type transistor may have a width substantially the same as a channel length of the planar type transistor. Thus, as the width of the gate electrode decreases, the channel length of the planar type transistor may decrease. Because an electric field may be affected by the reduced length channel of the transistor, the planar type transistor may not exhibit the same electrical characteristics due to an increased leakage current from a junction and/or a punch through of source-drain regions. When the DRAM device includes such a reduced-length transistor, the DRAM device may have deteriorated refresh characteristics.

Considering the above-mentioned problem, a recessed type transistor has been developed, which may include a gate electrode partially buried in a semiconductor substrate. When the transistor includes the recessed gate electrode, a channel between source-drain regions may have a relatively longer length in order that a leakage current may decrease. Additionally, a DRAM device including a recessed type transistor may have increased refresh characteristics.

In the manufacturing processes for forming the recessed type transistor, a recess may be formed on the semiconductor substrate to have a width narrower than a width of the recessed gate electrode. The narrower-width recess may not be properly formed on the semiconductor substrate using a photolithography process due to limitations of an exposure apparatus using during the photolithography process.

The recess may be formed on the semiconductor substrate through a thermal reflow of an etching mask; or an addition of chemicals into the etching mask after the etching mask may be formed on the semiconductor substrate to form the recess. However, a reproductivity of the process for forming the recess may deteriorate when the recess is formed by the thermal reflow of the etching mask or the addition of the chemicals into the etching mask. As a result, the recess may not have the desired width or the recess may not be formed in the proper position on the semiconductor substrate.

### SUMMARY OF THE INVENTION

Example embodiments of the present invention relate to a metal oxide semiconductor (MOS) transistor and a method of manufacturing the MOS transistor.

According to example embodiments of the present invention, a MOS transistor including a channel that has a length substantially larger than a width a gate electrode thereof is provided.

According to other example embodiments of the present invention, a method of manufacturing a MOS transistor including a channel that has a length substantially larger than a width of a gate electrode thereof is provided.

According to an example embodiment of the present invention, there is provided a MOS transistor that may include a substrate having an active region, a field region, a semiconductor pattern, a gate insulation layer, a gate electrode and/or source-drain regions. The semiconductor pattern may extend from the substrate and extend along the active region. The semiconductor pattern may extend along the length of the active region. The gate insulation layer may be formed on the substrate to cover the semiconductor pattern. The gate electrode may be formed on the semiconductor pattern. The gate electrode may have a linear shape (e.g., rectangular) extending substantially parallel to the semiconductor pattern. The length (extending in the first direction) of the gate electrode may be substantially greater than the width or the height of the gate electrode. The source-drain regions may be formed at portions of the active region adjacent to the gate electrode. The source-drain regions may extend substantially perpendicular to the semiconductor pattern.

In an example embodiment of the present invention, the semiconductor pattern may be formed by a selective epitaxial growth (SEG) process or any other appreciated method.

In an example embodiment of the present invention, the semiconductor pattern may be formed by partially etching the substrate.

In another example embodiment of the present invention, the semiconductor pattern may have a width substantially smaller than a width of a pattern formed by a conventional photolithography process.

In an example embodiment of the present invention, the semiconductor pattern may have a width of about 10 nm to about 90 nm.

According to another embodiment of the present invention, there is provided a method of manufacturing a MOS transistor. In the method of manufacturing the MOS transistor, an active region and/or a field region may be defined on a substrate. A semiconductor pattern may be formed on the active region. The semiconductor pattern may extend from the active region and may extend along the active region in a first direction. A gate insulation layer may be formed on the substrate to cover the semiconductor pattern. A gate electrode may be formed on the gate insulation layer, enclosing the semiconductor pattern. Source-drain regions may be formed on, or in, portions of the active region adjacent to the gate electrode in a second direction substantially perpendicular to the first direction.

In an example embodiment of the present invention, the semiconductor pattern may be formed by forming a hard mask pattern exposing a portion of the substrate, using the exposed portion of the substrate as a seed for a selective epitaxial growth process and/or removing the hard mask pattern. The hard mask pattern may be formed by forming a first mask pattern on the substrate having a first pitch, forming a dummy pattern making contact with a sidewall of the first mask pattern, forming a second mask pattern making contact with the dummy pattern and/or removing the dummy pattern between the first and the second mask patterns.

In an example embodiment of the present invention, the semiconductor pattern may be formed with a second pitch.

In an example embodiment of the present invention, the dummy pattern may have a width smaller than a width of a pattern formed by a conventional photolithography process. For example, the dummy pattern may have a width of about 10 nm to about 90 nm.

In an example embodiment of the present invention, the dummy pattern may be formed by forming a dummy layer on the substrate to cover the first mask pattern and/or etching the dummy layer by an anisotropic etching process.

In an example embodiment of the present invention, the dummy pattern may be removed by performing a wet etching process.

In an example embodiment of the present invention, the second mask pattern may be formed using a material with an etch selectivity substantially the same as the first mask pattern.

In an example embodiment of the present invention, the semiconductor pattern may be formed by forming a hard mask pattern on the substrate, forming the semiconductor pattern by partially etching a portion of the substrate exposed by the hard mask pattern and/or removing the hard mask pattern. The hard mask pattern may be formed by forming a dummy pattern on the substrate by a first pitch, forming a hard mask layer on the substrate to cover the dummy pattern, forming the hard mask pattern making contact with a sidewall of the dummy pattern and/or removing the dummy pattern.

In an example embodiment of the present invention, the first pitch may be larger than the second pitch of the semiconductor pattern. In another embodiment, the second pitch may be half of the first pitch.

In an example embodiment of the present invention, the hard mask pattern may have a width smaller than a width of a pattern formed by a conventional photolithography process. For example, the hard mask pattern may have a width of about 10 nm to about 90 nm.

In an example embodiment of the present invention, the dummy pattern may be removed by performing a wet etching process.

According to an example embodiment of the present invention, a MOS transistor may have a channel formed along a sidewall thereof. An upper surface of a semiconductor pattern may extend upwardly from a semiconductor substrate. The channel of the MOS transistor may have a length substantially larger than a width of a gate electrode of the MOS transistor. As a result, the MOS transistor including the semiconductor pattern may have increased electrical characteristics while decreasing the likelihood of a current leakage and/or a short channel effect. Additionally, the MOS transistor may be more easily formed through a photolithography process because adjacent photoresist patterns may be formed having an increased pitch in the photolithography process. Furthermore, because the semiconductor pattern may have a width smaller than a width of a pattern formed by a conventional photolithography process, the MOS transistor may be more highly integrated.

### BRIEF DESCRIPTION OF THE DRAWINGS

Example embodiments of the present invention will become readily apparent by reference to the following detailed description when considering in conjunction with the accompanying drawings. FIGS. 1-21 represent non-limiting example embodiments of the present invention as described herein.

FIG. 1 is a cross-sectional view illustrating a MOS transistor of a DRAM device in accordance with an example embodiment of the present invention;

FIG. 2 is a perspective view illustrating a MOS transistor of a DRAM device in accordance with an example embodiment of the present invention;

FIGS. 3 to 16 are cross-sectional views illustrating a method of manufacturing a MOS transistor in accordance with an example embodiment of the present invention;

FIG. 17 is an example perspective view illustrating a substrate including a semiconductor pattern; and

FIGS. 18 to 21 are cross-sectional views illustrating a method of manufacturing a MOS transistor in accordance with an example embodiment of the present invention.

### DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

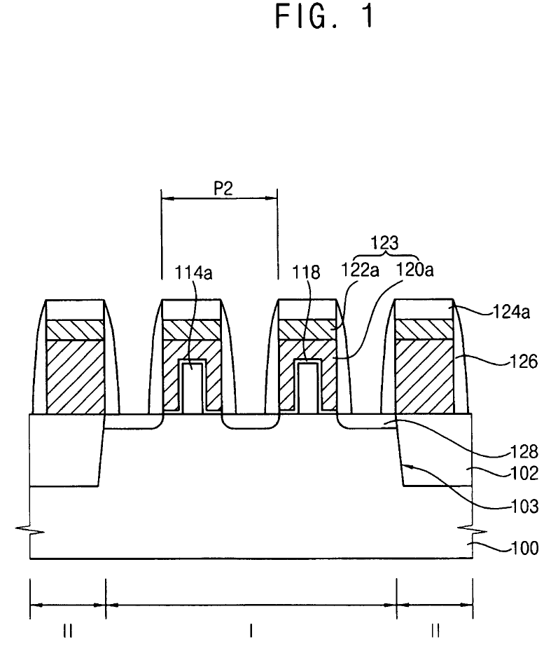

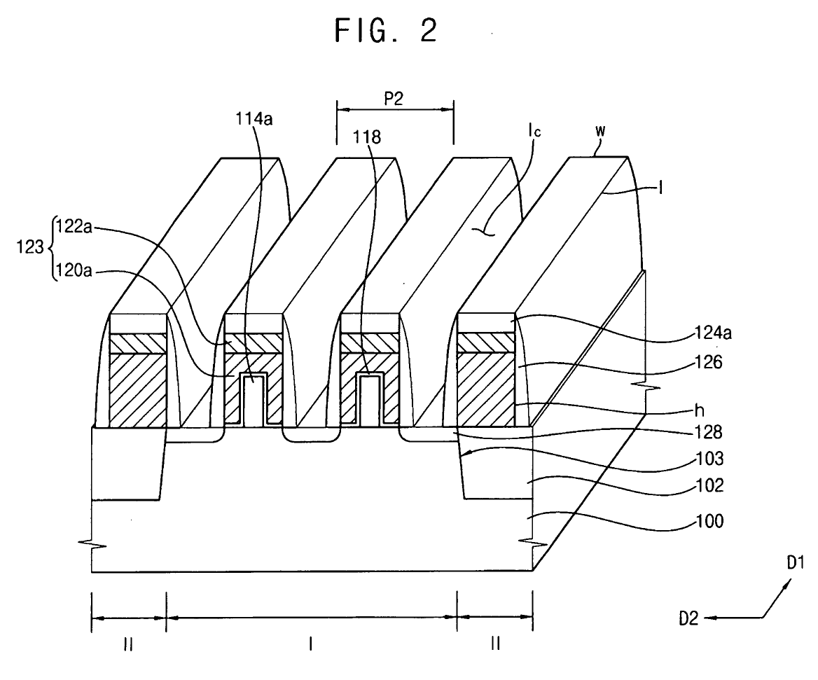

FIG. 1 is a cross-sectional view illustrating a MOS transistor of a DRAM device in accordance with an example embodiment of the present invention. FIG. 2 is a perspective view illustrating the MOS transistor of the DRAM device in FIG. 1.

In the DRAM device according to an example embodiment of the present invention, a size of a unit cell of the DRAM device may be about 8F² when a critical dimension of a line is F and a critical dimension of a space is F. However, the DRAM device may have a unit cell, which size is about 6F² or about 4F².

Referring to FIGS. 1 and 2, a substrate 100 may be divided into an active region I and/or a field region II through a trench isolation process. The field region II may be defined by a trench 103 and/or an isolation layer pattern 102 filling up the trench 103. The isolation layer pattern 102 may be formed of an oxide (e.g., silicon oxide). The field region 11 may be formed on sides of the active region I such that the active region I is surrounded by the field region II.

A semiconductor pattern 114a may be formed in the active region I of the substrate 100. The semiconductor pattern 114a may extend upwardly from the substrate in the active region I. The semiconductor pattern 114a may extend along the active region I in a first direction D1. For example, the semiconductor pattern 114a may extend from one end portion of the active region I to the other end portion of the active region I in the first direction D1.

In an example embodiment of the present invention, the semiconductor pattern 114a may include silicon grown from the active region I by a selective epitaxial growth (SEG) process. Other thin-film deposition techniques known in the art may also be used.

In another example embodiment of the present invention, the semiconductor pattern 114a may be formed by etching a portion of the substrate 100. The width of the semiconductor pattern 114a may be substantially narrower than the width of a pattern formed by a conventional photolithography process. For example, the semiconductor pattern 11 4a may have a width of about 10 nm to about 90 nm.

A gate insulation layer 118 may be formed on the semiconductor pattern 114a. The gate insulation layer 118 may cover the semiconductor pattern 114a and/or a portion of the active region I adjacent to the semiconductor pattern 114a.

In an example embodiment of the present invention, the gate insulation layer 118 may include an oxide (e.g., silicon oxide) formed by a thermal oxidation process. The gate insulation layer 118 of silicon oxide may be continuously formed on the portion of the active region I, a sidewall of the semiconductor pattern 114a and/or an upper surface of the semiconductor pattern 114a.

In another example embodiment of the present invention, the gate insulation layer 118 may include a metal oxide that has a dielectric constant higher than the dielectric constant of silicon oxide. The gate insulation layer 118 of metal oxide may be continuously formed on the field region 11, the active region I and/or the semiconductor pattern 114a.

A gate electrode 123 may be formed on the active region to cover the gate insulation layer 118. The gate electrode 123 may have a linear (e.g., rectangular) shape extending in the first direction D1. The length, l, (extending in the first direction D1) of the gate electrode 123 may be substantially greater than the width, w, or height, h, of the gate electrode 123. The gate electrode 123 may include a first conductive layer pattern 120a and/or a second conductive layer pattern 122a. The first conductive layer pattern 120a may substantially cover the gate insulation layer 118 formed on the semiconductor pattern 114a. The second conductive layer 122a may be positioned on the first conductive layer pattern 120a. The first conductive layer pattern 120a may include a first material that has a step coverage above the gate insulation layer 118. The second conductive layer pattern 122a may include a second material that has a specific resistance lower than a first material of the first conductive layer pattern 120a.

A hard mask pattern 124a may be formed on the gate electrode 123. The hard mask pattern 124a may include a nitride (e.g., silicon nitride).

A spacer 126 may be formed on sidewalls of the gate electrode 123 and/or the hard mask pattern 124a. The spacer 126 may include a nitride (e.g., silicon nitride).

Source-drain regions 128 may be formed on, or in, portions of the active region I adjacent to the gate electrode 123. The source/drain regions 128 may be formed along a second direction D2 substantially perpendicular to the first direction D1.

When the MOS transistor has a channel formed along sidewall portions and/or an upper portion of the semiconductor pattern 114a, the channel of the MOS transistor may have a length, l_{c}, larger than the width w of the gate electrode 123. Thus, decreasing the likelihood of a short channel effect in the MOS transistor and/or a current leakage from the MOS transistor.

When the MOS transistor is used as a cell transistor of a DRAM device, the DRAM device may have a decreased current leakage and/or increased refresh characteristics.

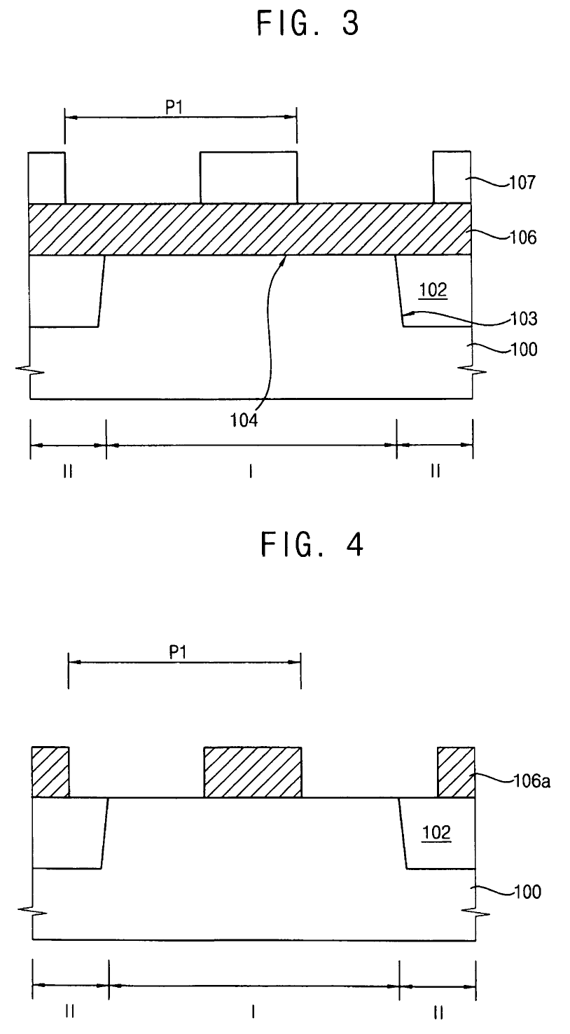

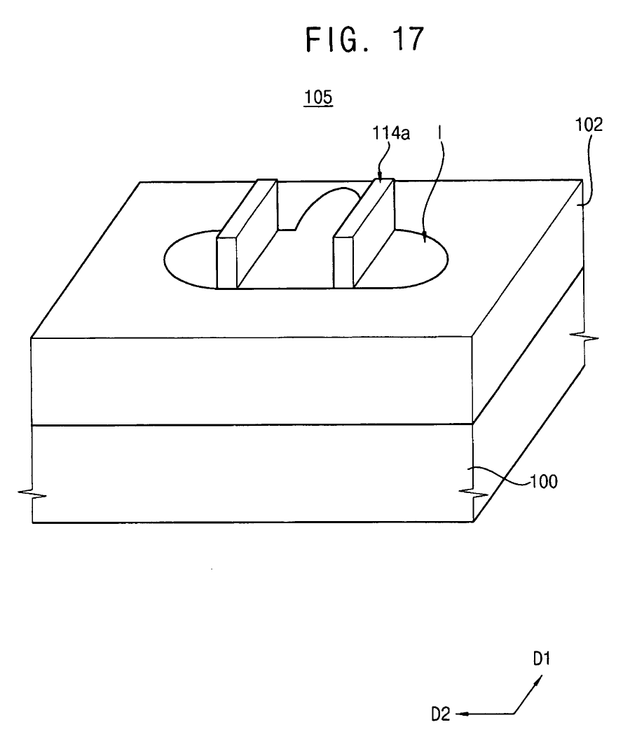

FIGS. 3 to 16 are cross-sectional views illustrating a method of manufacturing a MOS transistor in accordance with an example embodiment of the present invention. FIG. 17 is a perspective view illustrating a substrate including a semiconductor pattern.

Referring to FIG. 3, an isolation layer pattern 102 may be formed on a bare semiconductor substrate 100 to define an active region I from a field region II. The isolation layer 102 may be formed by a trench isolation process (e.g., a shallow trench isolation (STI) process).

A pad oxide layer and/or a hard mask layer may be sequentially formed on the bare semiconductor substrate 100. The pad oxide layer may be formed by a thermal oxidation process or a chemical vapor deposition (CVD) process. The pad oxide layer may include an oxide (e.g., silicon oxide). The pad oxide layer may be positioned between the hard mask layer such that the hard mask layer may not be directly contacting the bare semiconductor substrate 100. The hard mask layer may reduce a stress generated between the bare semiconductor substrate 100 and the hard mask layer. The hard mask layer may be formed using a nitride (e.g., silicon nitride).

After forming a photoresist pattern on the hard mask layer, the hard mask layer and/or the pad oxide layer may be partially etched using the photoresist pattern as an etching mask to form a pad oxide layer pattern and/or a hard mask pattern on the bare semiconductor substrate 100. A trench 103 may be formed on an upper portion of the bare semiconductor substrate 100 by partially etching the bare semiconductor substrate 100 using the hard mask pattern as an etching mask.

A sidewall oxide layer may be formed on a sidewall and/or a bottom face of the trench 103 to correct any etched damage to the bare semiconductor substrate 100 generated in the etching process for forming the trench 103. The sidewall oxide layer may decrease the likelihood of a current leakage from occurring in the bare semiconductor substrate 100. A nitride liner may be formed on the sidewall oxide layer.

An insulation layer pattern 102 may be formed on the hard mask pattern to fill the trench 103. The insulation layer may be formed using an oxide (e.g., silicon oxide). The insulation layer pattern 102 may be formed by a CVD process, a high density plasma-chemical vapor deposition (HDP-CVD) process, a spin on glass process, or any other appreciated method.

The insulation layer pattern 102 may be partially removed until the hard mask pattern is exposed in order to form the isolation layer pattern 102 in the trench 103. Then, the hard mask pattern and/or the pad oxide layer pattern may be removed from the bare semiconductor substrate 100.

A first preliminary mask layer 106 may be formed on the active region I and/or the field region II. The first preliminary mask layer 106 may be formed using a material that has an etching selectivity relative, or similar, to an etching selectivity of the bare semiconductor substrate 100. Thus, the bare semiconductor substrate 100 may not be etched in an etching process for etching the first preliminary mask layer 106. For example, the first preliminary mask layer 106 may be formed using an oxide (e.g., silicon oxide) or a nitride (e.g., silicon nitride).

When the first preliminary mask layer 106 includes silicon nitride, an additional pad oxide layer may be formed between the bare semiconductor substrate 100 and the first preliminary mask layer 106 in order to reduce a stress generated between the bare semiconductor substrate 100 and the first preliminary mask layer 106.

When the first preliminary mask layer 106 is formed using silicon oxide, a capping layer may be formed on the isolation layer 102 to decrease the likelihood of consuming the isolation layer 102 during subsequent etching processes.

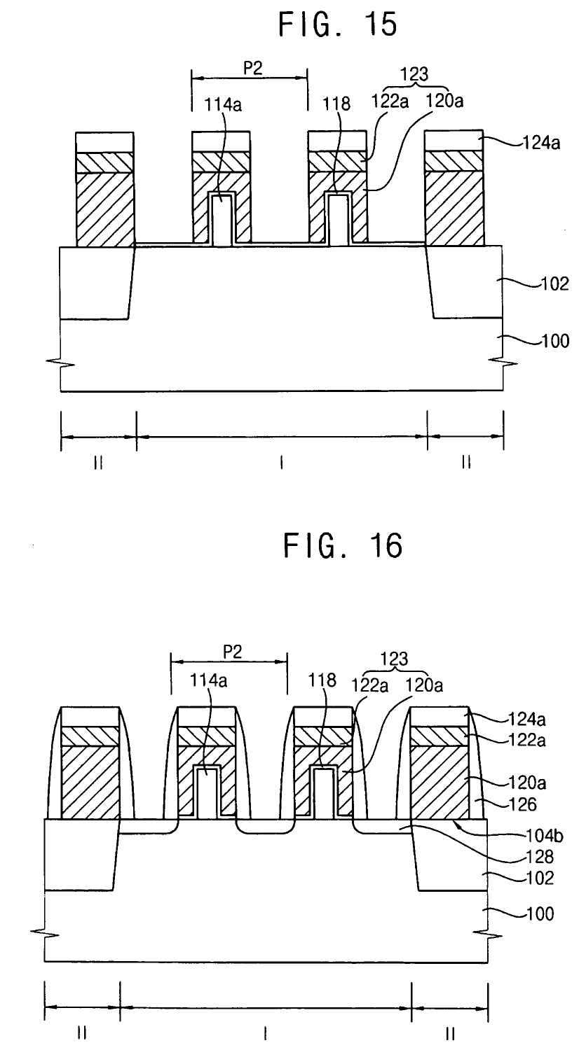

After forming a photoresist film on the first preliminary mask layer 106, the photoresist film may be exposed and developed to form photoresist patterns 107 on the first preliminary mask layer 106. The photoresist patterns 107 may function as etching masks for forming first mask patterns 106a (as shown in FIG. 4). Adjacent photoresist patterns 107 may be disposed by a first pitch P₁. In an example embodiment of the present invention, a pitch between neighboring gate electrodes 123 (as shown in FIG. 15) may be substantially the same as a pitch between adjacent semiconductor patterns 114a (as shown in FIG. 15). The pitch between the gate electrodes 123 and/or between the semiconductor patterns 114a is referred to as a second pitch P₂. See FIGS. 1 and 2. The first pitch P₁ may be larger than the second pitch P₂. The second pitch P₂ may be half of the first pitch P₁. When forming the photoresist patterns 107 with the first pitch P₁, the semiconductor patterns may be formed with the second pitch P₂. Thus, a process margin for the formation of the semiconductor patterns may be ensured.

Referring to FIG. 4, the first preliminary mask layer 106 may be etched using the photoresist patterns 107 as the etching masks, forming first mask patterns 106a on the bare semiconductor substrate 100. The first mask patterns 106a may be formed by an anisotropic etching process. The first mask patterns 106a may be formed having the first pitch P₁ in accordance with the photoresist patterns 107. In an example embodiment of the present invention, the first mask patterns 106a may have a linear shape crossing the active region I along a first direction D1. In another example embodiment of the present invention, the first mask patterns 106a may have island shapes disposed on the active region I along the first direction D1.

The photoresist patterns 107 may be removed from the first mask patterns 106a by an ashing process, a stripping process or any other appreciated method.

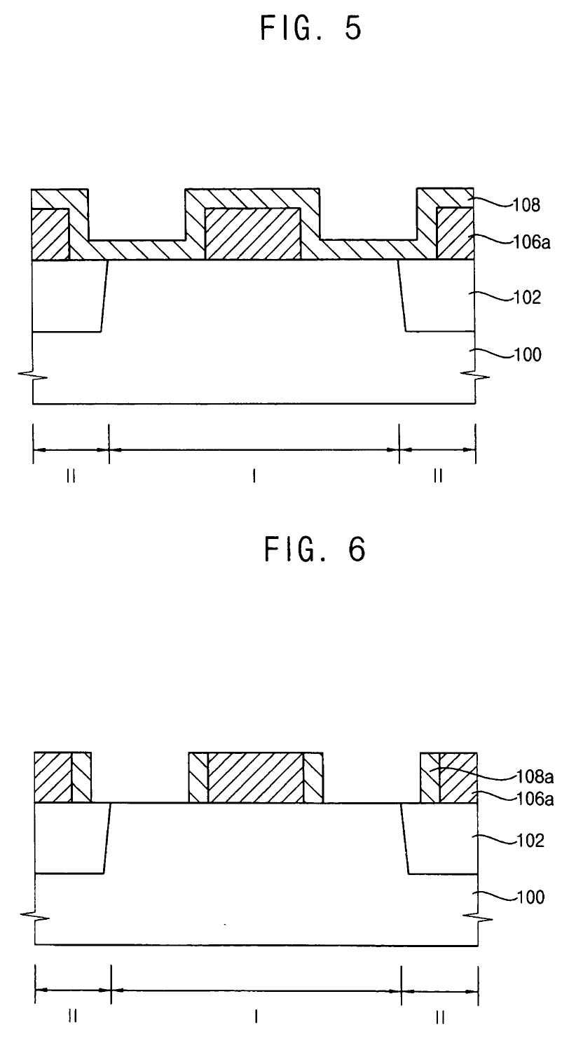

Referring to FIG. 5, a dummy layer 108 may be formed on the first mask patterns 106a and the bare semiconductor substrate 100. The dummy layer 108 may be formed using a material that has an etching selectivity with respect to an etching selectivity of the first mask patterns 106a. Thus, the first mask patterns 106a may not be etched in an etching process for etching the dummy layer 108. For example, the dummy layer 108 may include silicon oxide when the first mask patterns 106a are formed using silicon nitride. Alternatively, the dummy layer 108 may be formed using silicon nitride when the first mask patterns 106a include silicon oxide.

The dummy layer 108 formed on sidewalls of the first mask patterns 106a may have thickness substantially the same as desired widths of the semiconductor pattern 114a to be formed. Thus, the widths of the semiconductor pattern 114a may be determined by the thickness of the dummy layer 108. The semiconductor pattern 114a may have widths substantially smaller than the width of the pattern formed by a conventional photolithography process because the widths of the semiconductor patterns 114a may be controlled by adjusting the thickness of the dummy layer 108. For example, the width of the dummy layer 108 may be about 10 nm to about 90 nm.

Referring to FIG. 6, the dummy layer 108 may be anisotropically etched to form dummy patterns 108a on the sidewalls of the first mask patterns 106a. Each of the dummy patterns 108a may have a width substantially the same as the thickness of the dummy layer 108. Each of the dummy patterns 108a may function as a mold for forming the semiconductor pattern 114a corresponding to a channel of the MOS transistor.

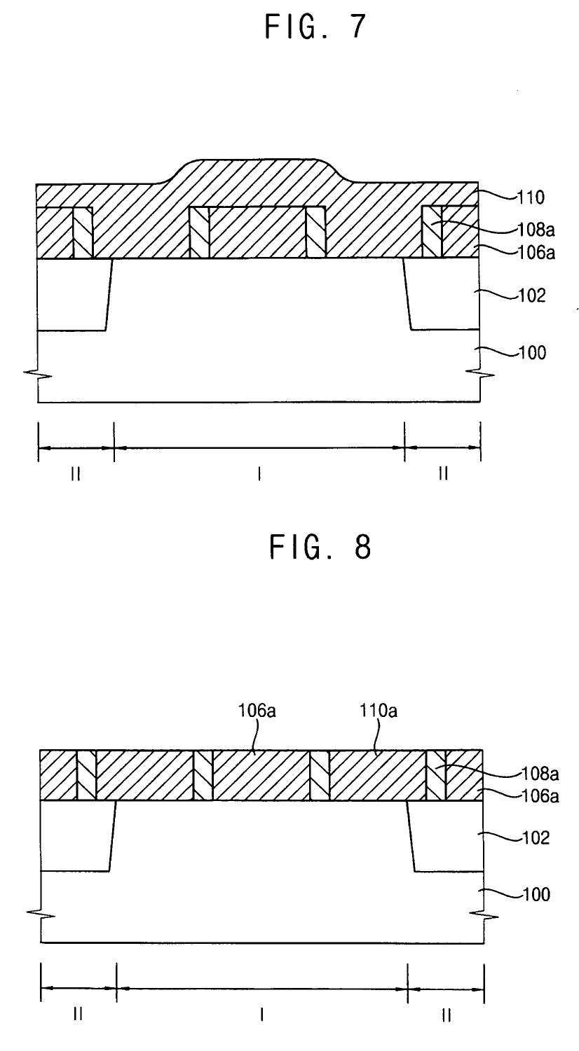

Referring to FIG. 7, a second preliminary mask layer 110 may be formed on the bare semiconductor substrate 100 to cover the dummy patterns 108a and/or the first mask patterns 106a. The lowest portion of an upper surface of the second preliminary mask layer 110 may be positioned over the first mask patterns 106a. The second preliminary mask layer 110 may be formed using a material having an etching selectivity substantially the same as that of the first mask pattern 106a.

Referring to FIG. 8, the second preliminary mask layer 110 may be partially removed until the first mask patterns 106a and the dummy patterns 108a are exposed. Thus, second mask patterns 110a may be formed between the dummy patterns 108a. The second mask patterns 110a may be formed by a chemical mechanical polishing (CMP) process or any other appreciated method.

After forming the second mask patterns 110a, the dummy patterns 108a may be buried between the first mask patterns 106a and/or the second mask patterns 110a. The first mask patterns 106a and/or the second mask patterns 110a may be alternately disposed on the bare semiconductor substrate 100. The dummy patterns 108a may be interposed between the first mask patterns 106a and the second mask patterns 110a.

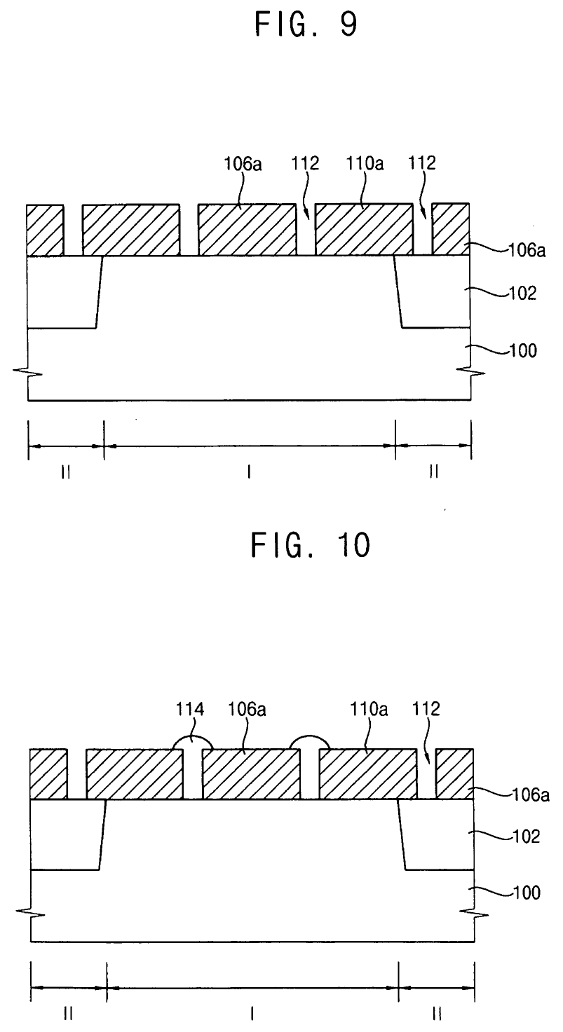

Referring to FIG. 9, the dummy patterns 108a may be removed to form openings 112 that expose portions of the bare semiconductor substrate 100. The dummy patterns 108a may be removed by a wet etching process to prevent etching damage to the portions of the bare semiconductor substrate 100 exposed through the openings 112.

In an example embodiment of the present invention, the first mask patterns 106a, the dummy patterns 108a and/or the second mask patterns 110a may have linear shapes crossing the active region I along the first direction D1. Thus, the openings 112 may have trench shapes extending on the active region 1 along the first direction D1 when the dummy patterns 108a are removed. Some of the openings 112 may expose portions of the active region I, whereas other openings 112 may expose portions of the field region II.

Referring to FIG. 10, preliminary semiconductor patterns 114 may be grown from the exposed portions of the active region I to fill the openings 112 by a selective epitaxial growth (SEG) process or any other appreciated method. The preliminary semiconductor patterns 114 may be formed on the portions of the bare semiconductor substrate 100 to function as seeds. When the bare semiconductor substrate 100 includes single crystalline silicon, the preliminary semiconductor patterns 114 also may include single crystalline silicon by performing an SEG process. Because the exposed portions of the field region II include oxide, the preliminary semiconductor patterns 114 may not be formed in the field region II.

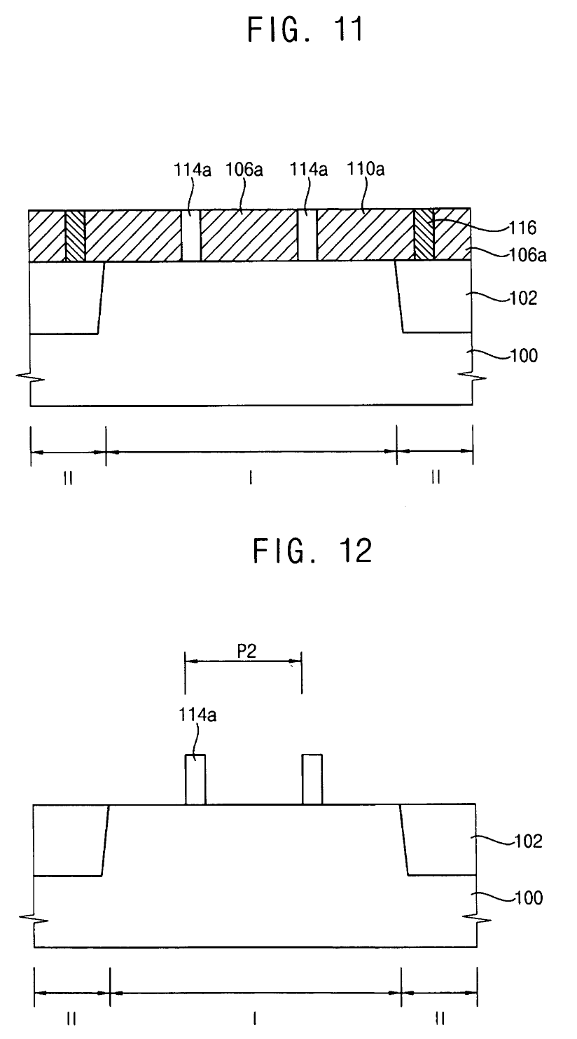

Referring to FIG. 11, a sacrificial layer may be formed on the first mask pattern 106a, the second mask pattern 110a and/or the preliminary semiconductor pattern 114. The sacrificial layer may fill the opening 112 positioned in the field region II.

The sacrificial layer and/or the preliminary semiconductor patterns 114 may be partially removed until the first and/or the second mask patterns 106a and 110a, respectively, are exposed to form semiconductor patterns 114a in the openings 112 positioned in the active region I and to simultaneously form sacrificial layer patterns 116 in the openings 112 positioned in the field region II.

Referring to FIGS. 12 and 17, the first mask patterns 106a, the second mask patterns 110a and/or the sacrificial layer patterns 116 may be removed from the bare semiconductor substrate 100. Thus, the semiconductor patterns 114a may remain on the active region I of the bare semiconductor substrate 100. A substrate 105 having the semiconductor patterns 114a is shown in FIG. 17. The substrate 105 may include the active region I defined by the isolation layer 102 corresponding to the field region II. Each of the semiconductor patterns 114a may extend from the active region I and may cross the active region I along the first direction D1.

The semiconductor pattern 114a may extend from one end portion of the active region I to the other end portion of the active region I along the first direction D1. The width of the semiconductor patterns 114a may be substantially the same as a width of the dummy pattern 108a because the semiconductor pattern 114a may be positioned in the opening 112 formed in accordance with a removal of the dummy pattern 108a. Therefore, the semiconductor pattern 114a may have the width substantially smaller than the width of the patterns formed by a conventional photolithography process. For example, the semiconductor pattern 114a may have the width of about 10 nm to about 90 nm.

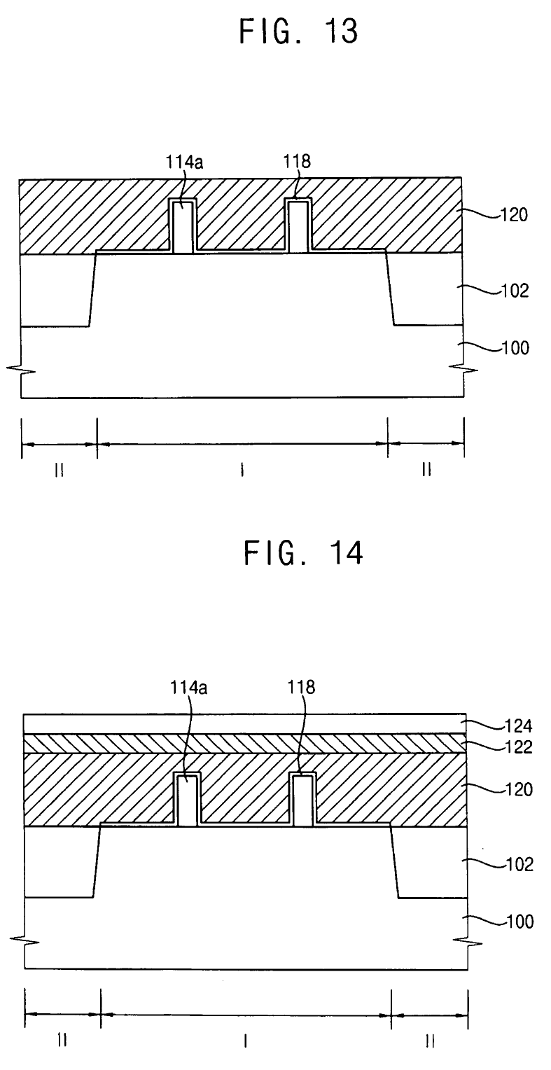

Referring to FIG. 13, a gate insulation layer 118 may be formed on the active region I to cover the semiconductor patterns 114a. The gate insulation layer 118 may be continuously formed on the active region 1, the sidewalls of the semiconductor patterns 114a and/or the upper surfaces of the semiconductor patterns 114a. The gate insulation layer 118 need not be formed on the field region II.

In an example embodiment of the present invention, the gate insulation layer 118 may include oxide formed using a thermal oxidation process.

In another example embodiment of the present invention, the gate insulation layer 118 may include a metal oxide having a higher dielectric constant formed through a CVD process, an atomic layer deposition (ALD) process or any other appreciated method. When the gate insulation layer 118 is formed using a metal oxide, the gate insulation layer 118 may be continuously formed on the field region II and the active region I to cover the semiconductor patterns 114a.

A first conductive layer 120 may be formed on the semiconductor substrate 100 including the gate insulation layer 118 to cover the semiconductor patterns 114a. The first conductive layer 120 may be formed by a low pressure chemical vapor deposition (LPCVD) process. The first conductive layer 120 may be formed using polysilicon doped with impurities. The impurities may be doped by a POCl₃ diffusion process, an ion implantation process, an in-situ doping process or any other appreciated method.

When forming the first conductive layer 120 using doped polysilicon by an LPCVD process, the first conductive layer 120 may fill a gap between the semiconductor patterns 114a such that sufficient step coverage thereof may be achieved, decreasing the likelihood of voids. The upper surface of the first conductive layer 120 may be positioned over the upper surfaces of the semiconductor patterns 114a.

The first conductive layer 120 may be partially removed by a CMP process to planarize an upper portion of the first conductive layer 120. An upper surface of the planarized first conductive layer 120 may be positioned over the upper surfaces of the semiconductor patterns 114a.

Referring to FIG. 14, a second conductive layer 122 may be formed on the first conductive layer 120. The second conductive layer 122 may be formed using a material that has a specific resistance lower than the resistance of the first conductive layer 120. The second conductive layer 122 may be formed of metal or metal silicide. For example, the second conductive layer 122 may be formed of tungsten silicide.

A hard mask layer 124 may be formed on the second conductive layer 122. The hard mask layer 124 may be formed using a nitride (e.g., silicon nitride).

Referring to FIG. 15, after forming a photoresist film on the hard mask layer 124, the photoresist film may be exposed and developed to form a photoresist pattern (not shown) on the hard mask layer 124.

Using the photoresist pattern as an etching mask, the hard mask layer 124 may be partially etched to form a hard mask pattern 124a on the second conductive layer 122. The photoresist pattern may be removed from the hard mask pattern 124a by an ashing process, a stripping process or any other technique known in the art.

The second and the first conductive layers 122 and 120 may be sequentially etched using the hard mask pattern 124a as an etching mask, forming gate electrodes 123 on the active region I. The gate electrodes 123 may include first conductive layer patterns 120a and/or second conductive layer patterns 122a. The first conductive layer patterns 120a may cover the sidewalls and/or the upper surfaces of the semiconductor patterns 114a The second conductive layer patterns 122a may be positioned on the first conductive layer patterns 120a. Each of the gate electrodes 123 may have a linear shape extending along the first direction. The second pitch P₂ between adjacent gate electrodes 123 may be a half of the first pitch P₁.

Referring to FIG. 16, a nitride layer may be formed on the semiconductor substrate 100 to cover the hard mask pattern 124a. The nitride layer may be anisotropically etched to form spacers 126 on sidewalls of the gate electrode 123 and/or the hard mask pattern 124a.

Impurities may be implanted into portions of the active region I adjacent to the gate electrodes 123 such that source-drain regions 128 may be formed on, or in, the portions of the active region 1. The source/drain regions 128 may be formed in the second direction D2 substantially perpendicular to the first direction D1.

As described above, the semiconductor patterns 114a may have smaller widths using the photoresist patterns 107 formed with the first pitch P₁ about twice the size of the second pitch P₂, between the semiconductor patterns 114a. The semiconductor pattern 114a may have a narrower width than the width of the pattern formed by a conventional photolithography process.

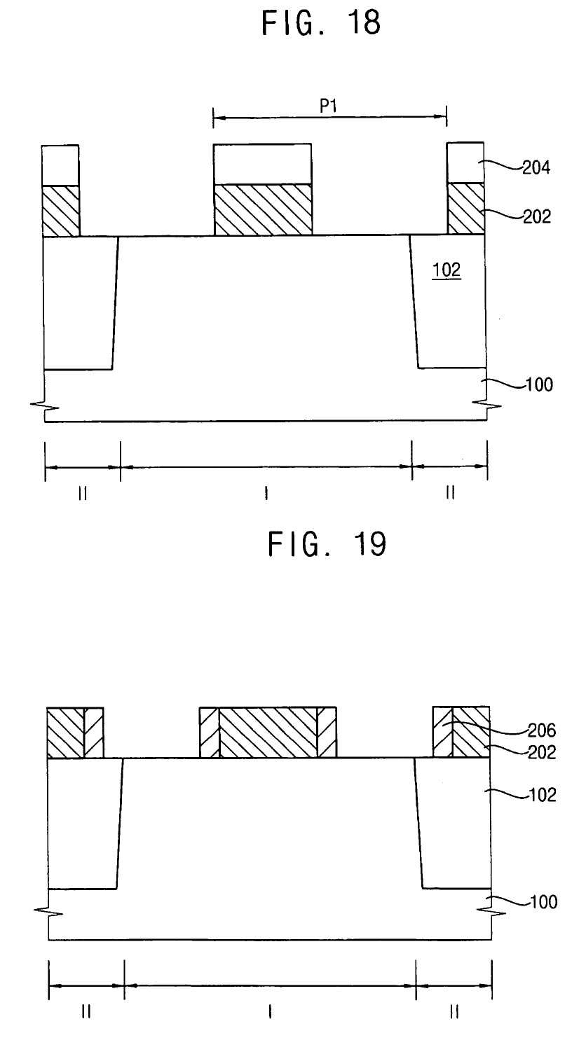

FIGS. 18 to 21 are cross-sectional views illustrating a method of manufacturing a MOS transistor in accordance with an example embodiment of the present invention.

Referring to FIG. 18, an isolation layer 102 may be formed on a semiconductor substrate 100 through a process substantially the same as the process described with reference to FIG. 3. The isolation layer 102 may define an active region I and/or a field region II. The isolation layer 102 may be deeper than semiconductor patterns 210 (see FIG. 21) formed by partially etching the semiconductor substrate 100.

A dummy layer may be formed on the semiconductor substrate 100 having the isolation layer 102. The dummy layer may be formed using a material that has an etching selectivity with respect to the semiconductor substrate 100. The semiconductor substrate 100 need not be etched in a successive etching process for etching the dummy layer. For example, the dummy layer may be formed using an oxide (e.g., silicon oxide) or a nitride (e.g., silicon nitride).

When the dummy layer includes silicon nitride, a pad oxide layer (not shown) may be formed between the semiconductor substrate 100 and the dummy layer in order to decrease stress generated in the process for forming the dummy layer.

When the dummy layer is formed using silicon oxide, a capping layer (not shown) may be formed on the isolation layer 102 to decrease the likelihood of consuming the isolation layer 102 in successive etching processes.

A photoresist film may be formed on the dummy layer. The photoresist film may be exposed and developed to form a photoresist pattern 204 on the dummy layer. Adjacent photoresist patterns 204 may be disposed by a first pitch Pi. The dummy layer may be etched using the photoresist patterns 204 to form dummy patterns 202 for forming hard mask patterns 206.

In other example embodiments of the present invention, adjacent gate electrodes may be formed by a second pitch P₂ substantially the same as an adjacent semiconductor patterns 210. The second pitch between adjacent gate electrodes may be substantially twice the length the first pitch P₁ between adjacent photoresist patterns 204.

The dummy patterns 202 may be formed by anisotropically etching the dummy layer using the photoresist patterns 204 as etching masks. The dummy patterns 202 may be formed having the first pitch P₁ in accordance with the photoresist patterns 204. Each of the dummy patterns 202 may have a linear shape extending on the bare semiconductor substrate 100 in the first direction D1.

The photoresist patterns 204 may be removed by an ashing process, a stripping process or any other technique known in the art.

Referring to FIG. 19, a hard mask layer may be formed on the bare semiconductor substrate 100 to cover the dummy patterns 202. The hard mask layer may be continuously formed on sidewalls and/or upper surfaces of the dummy patterns 202. The hard mask layer may be formed using a material that has an etching selectivity relative to the dummy patterns 202. The dummy patterns 202 need not be etched in an etching process for etching the hard mask layer.

When the dummy patterns 202 include silicon oxide, the hard mask layer may be formed using silicon nitride. When the dummy patterns 202 include silicon nitride, the hard mask layer may be formed using silicon oxide.

The hard mask layer may have a thickness substantially identical to the semiconductor patterns 210 successively formed by partially etching the bare semiconductor substrate 100. The hard mask layer may have a thickness smaller than a width of a pattern formed by a conventional photolithography process.

The hard mask layer may be anisotropically etched to form hard mask patterns 206 on the sidewalls of the dummy patterns 202. The hard mask patterns 206 may have widths substantially the same as the thickness of the hard mask layer. Each of the semiconductor patterns 210 may be formed using the hard mask pattern 206 to function as a channel of the MOS transistor.

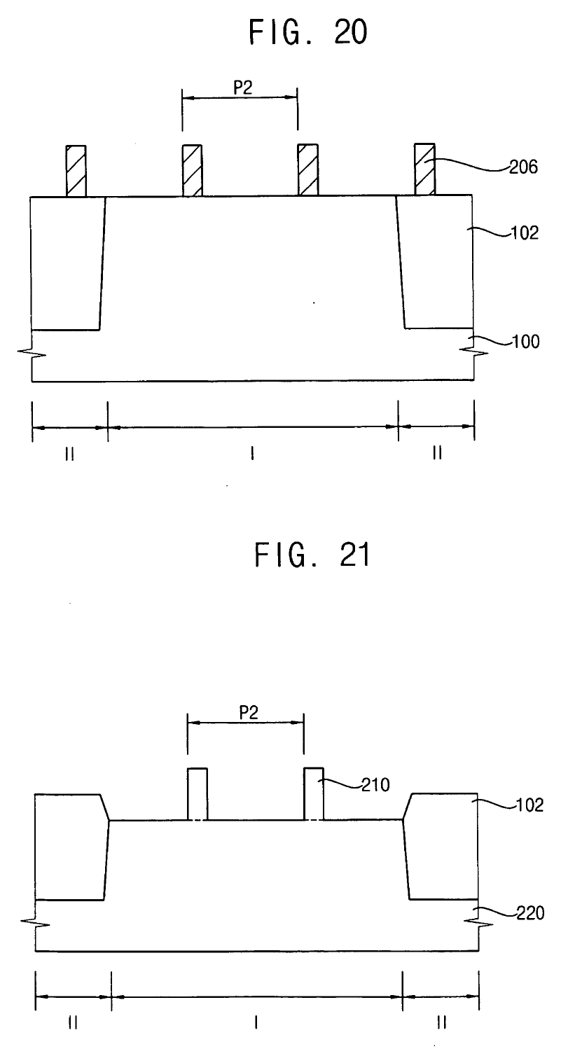

Referring to FIG. 20, the dummy patterns 202 may be selectively removed from the bare semiconductor substrate 100. The active region I of the bare semiconductor substrate 100 may be partially exposed after removing the dummy layer patterns 202.

Referring to FIG. 21, the active region I of the bare semiconductor substrate 100 may be partially etched using the hard mask patterns 206 as etching masks such that the semiconductor patterns 210 are formed on the active region I. The semiconductor patterns 210 may cross the active region I in the first direction D1. After removing the hard mask pattern 206, the substrate 100 including the semiconductor patterns 210 may be formed.

The semiconductor patterns 210 may extend from one end portion of the active region I to the other end portion of the active region I along the first direction D1. Because the semiconductor patterns 210 may be formed using the hard mask patterns 206, the semiconductor patterns 210 may have widths substantially the same as the width of the hard mask patterns 206. The semiconductor patterns 210 may have widths smaller than the width of the pattern formed by the conventional photolithography process. For example, each of the semiconductor patterns 210 may have a width of about 10 nm to about 90 nm.

The MOS transistor may be formed on the substrate 220 through processes substantially the same as the processes described with reference to FIGS. 13 to 17.

As described above, the semiconductor patterns 210 may be formed using the photoresist patterns 204 disposed by the first pitch P₁ about twice the length of the second pitch P₂ between adjacent semiconductor patterns 210. Thus, the likelihood of obtaining a desired process margin during the photolithography process may increase whereas the width of the semiconductor pattern 210 may be smaller than the width of the pattern formed by the conventional photolithography process.

According to example embodiments of the present invention, a MOS transistor may have a channel formed along a sidewall and/or an upper surface of a semiconductor pattern. The upper surface of the semiconductor pattern may extend upwardly from a semiconductor substrate. The length of the MOS transistor channel may be longer than the width of a gate electrode of the MOS transistor. The MOS transistor including the semiconductor pattern may have increased electrical characteristics while decreasing the likelihood of a current leakage and/or a short channel effect.

Additionally, the MOS transistor may be more easily formed through a photolithography process because adjacent photoresist patterns may be formed having an increased pitch during the photolithography process. Furthermore, because the semiconductor pattern may have a width smaller than the width of a pattern formed through a conventional photolithography process, the MOS transistor may be more highly integrated.

The foregoing is illustrative of the example embodiments of the present invention and is not to be construed as limiting thereof. Although a few example embodiments of the present invention have been described, those skilled in the art will readily appreciate that many modifications are possible in the example embodiments without materially departing from the novel teachings and advantages of this invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A MOS transistor comprising:
a substrate having an active region and a field region;
a semiconductor pattern extending from the substrate and along the active region;
a gate insulation layer formed on the semiconductor pattern and a portion of the substrate;
a gate electrode formed on the gate insulation layer, the gate electrode having a linear shape extending substantially parallel to the semiconductor pattern; and
source-drain regions formed on portions of the active region adjacent to the gate electrode, the source-drain regions extending substantially perpendicular to the semiconductor pattern.

2. The MOS transistor of claim 1, wherein the semiconductor pattern is formed by performing a selective epitaxial growth (SEG) process.

3. The MOS transistor of claim 1, wherein the semiconductor pattern is formed by partially etching the substrate.

4. The MOS transistor of claim 1, wherein a pitch of the semiconductor pattern is substantially the same as a pitch of the gate electrode.

5. The MOS transistor of claim 1, wherein the semiconductor pattern has a width of about 10 nm to about 90 nm.

6. The MOS transistor of claim 1, wherein the field region is formed on sides of the active region.

7. A method of manufacturing a MOS transistor, comprising:
defining an active region and a field region on a substrate;
forming a semiconductor pattern on the active region wherein an upper surface of the semiconductor pattern extends from the substrate and the semiconductor pattern extends along the active region in a first direction;
forming a gate insulation layer on the substrate to cover the semiconductor pattern;
forming a gate electrode on the gate insulation layer; and
forming source-drain regions at portions of the active region adjacent to the gate electrode along a second direction substantially perpendicular to the first direction.

8. The method of claim 7, wherein forming the semiconductor pattern includes forming a hard mask pattern exposing a portion of the substrate; performing a selective epitaxial growth process using the exposed portion of the substrate as a seed for growth; and removing the hard mask pattern.

9. The method of claim 8, wherein forming the hard mask pattern includes forming a first mask pattern on the substrate by a first pitch P₁; forming a dummy pattern making contact with a sidewall of the first mask pattern; forming a second mask pattern making contact with the dummy pattern; and removing the dummy pattern between the first and the second mask patterns.

10. The method of claim 9, wherein the semiconductor pattern is formed with a second pitch P₂, wherein the expression P₁≈P₂ is satisfied.

11. The method of claim 10, wherein the gate electrode is formed with a third pitch P₃, wherein the expression P₃≈P₂ is satisfied.

12. The method of claim 9, wherein the dummy pattern is formed with a width of about 10 nm to about 90 nm.

13. The method of claim 9, wherein forming the dummy pattern includes forming a dummy layer on the substrate to cover the first mask pattern; and etching the dummy layer by performing an anisotropic etching process.

14. The method of claim 9, wherein removing the dummy pattern includes performing a wet etching process.

15. The method of claim 9, wherein forming the second mask pattern includes using a material having an etching selectivity substantially the same as an etching selectivity of the first mask pattern.

16. The method of claim 7, wherein forming the semiconductor pattern includes forming a hard mask pattern on the substrate; etching a portion of the substrate exposed by the hard mask pattern; and removing the hard mask pattern.

17. The method of claim 16, wherein forming the hard mask pattern includes forming a dummy pattern on the substrate by a first pitch P₁; forming a hard mask layer on the substrate to cover the dummy pattern; forming the hard mask pattern making contact with a sidewall of the dummy pattern; and removing the dummy pattern.

18. The method of claim 17, wherein the semiconductor pattern is formed with a second pitch P₂, wherein the expression P₂<P₁ is satisfied.

19. The method of claim 17, wherein the gate electrode is formed with a third pitch P₃, wherein the expression P₃<P₁ is satisfied.

20. The method of claim 17, wherein the hard mask pattern is formed with a width of about 10 nm to about 90 nm.

21. The method of claim 17, wherein removing the dummy pattern includes performing a wet etching process.

22. The method of claim 7, wherein defining the active region and the field region includes dividing the substrate into the active region and the field region and forming the field region on sides of the active region.
